(19) United States
(12) Patent Application Publication
(10) Pub. No.: US 2023/0361260 A1
(43) Pub. Date: Nov. 9, 2023

(54) MULTILAYER ASSEMBLY WITH ELECTRICAL COMPONENT

(71) Applicant: SIGNIFY HOLDING B.V., EINDHOVEN (NL)

(72) Inventor: Pieter Joseph Clara VAN DER WEL, HEERLEN (NL)

(21) Appl. No.: 18/028,556

(22) PCT Filed: Sep. 30, 2021
(86) PCT No.: PCT/EP2021/076896

§ 371 Date: Mar. 26, 2023

(30) Foreign Application Priority Data
Oct. 1, 2020 (EP) 20199516.4

(51) Int. Cl. H01L 33/62; H01L 33/00; H01L 33/20

(52) U.S. Cl. CPC H01L 33/62; H01L 33/005; H01L 33/20; H01L 2933/0066

(57) ABSTRACT

The invention provides a light generating device (1000) comprising (a) a first interconnect (110), (b) a second interconnect (120), (c) a solid state light source (130), and (d) a multilayer stack (200) comprising a first multilayer (210) and a second multilayer (220), wherein: each multilayer (210,220) of the multilayer stack (200) comprises (i) a flexible support layer (250), and (ii) a conductive layer (230); the first interconnect (110) connects the solid state light source (130) and the conductive layer (230) of the first multilayer (210); the first multilayer (210) comprises an opening (215), wherein at least part of the second interconnect (120) is arranged in the opening (215); the second interconnect (120) connects the solid state light source (130) and the conductive layer (230) of the second multilayer (220); and the first interconnect (110), the second interconnect (120), and the conductive layers (230) are each individually one or more of thermally conductive and electrically conductive.

### FIELD OF THE INVENTION

The invention relates to an assembly comprising a first interconnect, a second interconnect, an electrical component and a multilayer stack. The invention further relates to a light generating device comprising the assembly. The invention further relates to a method for providing the assembly.

### BACKGROUND OF THE INVENTION

Printed circuit boards with lighting components are known in the art. For instance, U.S. Pat. No. 10,524,320B1 describes linear lighting including a narrow, elongate printed circuit board (PCB). A plurality of LED light engines are disposed on the PCB and are electrically connected to it. The PCB is divided physically and electrically into repeating blocks, which are physically in series with one another and electrically in parallel. A pair of conductors extends the entire length of the linear lighting. Each of the conductors has a service loop corresponding to the position of each of the cut points. A covering encapsulates the PCB and the pair of conductors. The service loops in the conductors provide for additional length of conductor when the linear lighting is cut at a cut point, so that the linear lighting can be connected to power.

### SUMMARY OF THE INVENTION

There may be a trend among Linear LED modules towards making printed circuit board (PCB) modules more narrow. However, the LEDs still need room for mechanical placement and preferably some additional surface for heat spreading in a conductive layer. At the same time more complex assemblies are designed, which may require more routing in the conductive layer. The need for space on the PCB may thus conflict with the desire for more narrow modules. The prior art may describe large multilayer PCBs and FPCs. However, these may be relatively expensive.

Hence, it is an aspect of the invention to provide an alternative multilayer assembly, which preferably further at least partly obviates one or more of above-described drawbacks. The present invention may have as object to overcome or ameliorate at least one of the disadvantages of the prior art, or to provide a useful alternative.

Hence, in a first aspect the invention may provide an assembly comprising one or more of a first (conductive) interconnect, a second (conductive) interconnect, an electrical component, and a multilayer stack. The multilayer stack may especially comprise a first multilayer and a second multilayer. In embodiments, each multilayer of the multilayer stack may comprise a flexible support layer, especially a flexible support layer comprising a material selected from the group comprising polyimide, polyester, and epoxy glass. In further embodiments, each multilayer of the multilayer stack may comprise a conductive layer. The first interconnect may connect the electrical component and the conductive layer of the first multilayer. The first multilayer may comprise an opening, especially wherein at least part of the second interconnect is arranged in the opening. The second interconnect may connect the electrical component and the conductive layer of the second multilayer, especially via the opening. In further embodiments, the first interconnect, the second interconnect, and the conductive layers may each individually be one or more of thermally conductive and electrically conductive. In embodiments, at least one of the conductive layers may be electrically conductive. In particular, in further embodiments, at least one of the conductive layers may be electrically conductive and may be electrically coupled with the electrical component. In further embodiments, at least one of the conductive layers may be thermally conductive. In particular, in further embodiments, at least one of the conductive layers may be thermally conductive and may be thermally coupled with the electrical component.

The assembly of the invention may provide the benefit that more complexity is facilitated, even in a narrow assembly. In particular, the invention may provide a multilayer PCB assembly out of one or more thin flexible film substrates and more than one conductive layer, such as two or more copper layers.

In particular, the interconnects between layers may be provided in a convenient manner, especially during a Surface Mount Technology (SMT) process. For example, the interconnect between two multilayer films may be provided during the SMT process by establishing a solder bridge under the leads of an SMT component. As the flexible support layer may be relatively thin, the solder bridge can be kept thin as well. The addition of the second flexible support layer provides additional functional area, for example for Cu routing, especially while keeping the assembly narrow.

Further, the assembly of the invention may be beneficial for temperature management. In particular, the conductive layer of one (or more) multilayers can be dedicated to functional electrical couplings, whereas the conductive layer of one (or more) other multilayers can be thermally conductive and may be dedicated to temperature management.

This the invention may provide advantages in terms of thermal management and/or electrically e.g. better reliability/more complexity. For example, the light generating device may have improved thermal management e.g. because of multiple conductive layers which are thermally conductive. For example, the light generating device may have an improved electrical design e.g. because of multiple conductive layers which are electrically conductive. It may improve reliability e.g. due to a lower risk of a short circuit and/or a more complex driving/control circuitry design for one or more solid state light sources is possible.

Hence, in specific embodiments, the invention provides an assembly comprising (a) a first interconnect, (b) a second interconnect, (c) an electrical component, and (d) a multilayer stack comprising a first multilayer and a second multilayer, wherein: each multilayer of the multilayer stack comprises (i) a flexible support layer and (ii) a conductive layer; the first interconnect connects the electrical component and the conductive layer of the first multilayer; the first multilayer comprises an opening, wherein at least part of the second interconnect is arranged in the opening; the second interconnect connects the electrical component and the conductive layer of the second multilayer; and the first interconnect, the second interconnect, and the conductive layers are each individually one or more of thermally conductive and electrically conductive.

Hence, the invention may provide an assembly, especially a PCB assembly.

The assembly may comprise a first (conductive) interconnect and a second (conductive) interconnect. The interconnects may be configured to connect two elements, especially to thermally (and/) or electrically connect two elements.

The first interconnect may especially be thermally or electrically conductive. Similarly, the second interconnect may especially be thermally or electrically conductive.

The assembly may further comprise an electrical component. The term “electrical component” may also refer to a plurality of electrical components. The term “electrical component” may herein also refer to an electronic component. The electronic component may include an active or a passive electronic component. An active electronic component may be any type of circuit component with the ability to electrically control electron flow (electricity controlling electricity). Examples thereof are diodes, especially light emitting diodes (LED). LEDs are herein also indicated with the more general term solid state lighting devices or solid state light sources. Hence, in embodiments the electronic component comprises an active electronic component. Especially, the electronic component comprises a solid state light source. In specific embodiments, the electronic component comprises a (high power) ceramic LED.

Other examples of active electronic components may include power sources, such as a battery, a piezo-electric device, an integrated circuit (IC), and a transistor. In an embodiment, the electronic component comprises a driver. In yet other embodiments, the electronic component may include a passive electronic component. Components incapable of controlling current by means of another electrical signal are called passive devices. Resistors, capacitors, inductors, transformers, etc. can be considered passive devices. In an embodiment, the electronic component may include an RFID (Radio-frequency identification) chip. A RFID chip may be passive or active. Especially, the electronic component may include one or more of a solid state light source (such as a LED), a RFID chip, and an IC. The term “electronic component” may also refer to a plurality of alike or a plurality of different electronic components.

The assembly may further comprise a multilayer stack. The multilayer stack may comprise two or more multilayers, especially (at least) a first multilayer and a second multilayer. The term “multilayer” may herein especially refer to a subunit comprising two or more layers.

In embodiments, each multilayer of the multilayer stack may comprise a flexible support layer, especially a flexible support layer comprising a material selected from the group comprising polyimide, polyester, and epoxy glass. In particular, the flexible support layer may comprise one or more of a (foil) polyester film, a polyimide film, a polyimide fluorocarbon film, and an epoxy glass coating (on a conductive layer), especially one or more of a polyimide film, and a polyimide fluorocarbon film. Hence, the flexible support layer may especially comprise polyimide, such as e.g. imide monomer polyimide, or such as e.g. poly(4,4′-oxydiphenylene-pyromellitimide).

The flexible support layer may especially be electrically insulating.

In further embodiments, each multilayer of the multilayer stack may comprise a conductive layer, especially an electrically conductive layer, or especially a thermally conductive layer.

In further embodiments, the conductive layer may comprise a thermally conductive material, especially a thermally conductive material selected from the group comprising gold, silver, and copper, especially gold, or especially copper.

In further embodiments, the conductive layer may comprise an electrically conductive material, especially an electrically conductive material selected from the group comprising gold, silver, and copper, especially gold, or especially copper.

The conductive layer may further be selected to be solderable (also see below). Hence, in embodiments, the conductive layer may comprise a material selected from the group comprising gold, and copper.

In further embodiments, each multilayer of the multilayer stack may comprise a flexible support layer and a conductive layer. Hence, in embodiments, the multilayer stack may comprise one or more multilayers selected from the group comprising a copper clad foil polyester film, a copper clad polyimide film, a copper clad polyimide fluorocarbon film, and a thin epoxy glass coated copper sheet.

In embodiments, a multilayer of the multilayer stack may comprise two conductive layers, i.e., it may comprise conductive layers arranged at opposite sides of the flexible support layer.

In embodiments, the multilayer stack may comprise an equal number of flexible support layers and conductive layers. However, in further embodiments, the multilayer stack may comprise n flexible support layers and n+1 conductive layers.

In further embodiments, the multilayers in the multilayer stack may be arranged such that the conductive layers are electrically separated, i.e., such that the conductive layers are not in direct electrical contact. In particular, each conductive layer may be physically separated from each other conductive layer.

In embodiments, the first interconnect may connect the electrical component and the conductive layer of the first multilayer. Hence, the electrical component may be functionally coupled to the conductive layer of the first multilayer via the first interconnect. In particular, the first multilayer may be a flexible printed circuit (FPC) and the electrical component may be functionally coupled to the first multilayer via the first interconnect.

In embodiments, the first multilayer may comprise an opening, especially a through hole. The opening may especially extend through the layers of the first multilayer, i.e., the multilayer may comprise a plurality of layers stacked along a first dimension, especially parallel to a multilayer stack height (see below), and the opening may provide a through hole through the first multilayer along the first dimension.

In further embodiments, at least part of the second interconnect may be arranged in the opening.

In further embodiments, the second interconnect may connect the electrical component and the conductive layer of the second multilayer (via the opening). Hence, the electrical component may be functionally coupled to the conductive layer of the second multilayer via the second interconnect.

In particular, the second interconnect may connect the electrical component and the conductive layer of the second multilayer via the opening.

In embodiments, each of the first interconnect, the second interconnect, and the conductive layers are individually one or more of thermally conductive and electrically conductive.

In embodiments, one or more of the first interconnect and the second interconnect may comprise a connecting component, especially an electrically connecting component, such as a metal pin or a (metal) wire. In particular, the first interconnect (or the second interconnect) may comprise one or more connecting components, especially electrically connecting components.

In further embodiments, the first interconnect (or the second interconnect) may comprise a solder material. The term “solder material” may herein refer to a fusible metal alloy used to provide a (permanent) bond between (metal) elements. Hence, the solder material may especially be one or more of thermally conductive and electrically conductive, especially electrically conductive.

In further embodiments, the first interconnect may consist of the solder material, i.e., the solder material may connect the electrical component and the conductive layer of the first multilayer.

Similarly, in further embodiments, the second interconnect may consist of the solder material, i.e., the solder material may connect the electrical component and the conductive layer of the second multilayer.

In embodiments, the assembly may comprise a thermal connector, especially an electrically insulated thermal connector. The thermal connector may especially comprise a heat slug. The thermal connector may especially be thermally coupled to the electrical component. Further, the thermal connector may especially be thermally coupled to the conductive layer of the first multilayer or to the conductive layer of the second multilayer, especially to the conductive layer of the first multilayer, wherein the conductive layer of the first multilayer is thermally conductive, or especially to the conductive layer of the second multilayer, wherein the conductive layer of the second multilayer is thermally conductive.

The term “heat slug” may herein especially refer to a thermally conductive construction onto which an electrical component, especially a semiconductor (crystal), is attached. For example, the heat slug may comprise an insulating ceramic platelet with an exterior gold layer for soldering purposes.

In further embodiments, the conductive layer of the first multilayer may comprise a heat sink. In further embodiments, the conductive layer of the second multilayer may comprise a heat sink.

In embodiments, the thermal connector may especially comprise a thermally conductive material selected from the group comprising gold, silver, and copper.

In embodiments, the electrical component may comprise an electrical connector, especially wherein the electrical connector is electrically coupled to the conductive layer of the first multilayer (via the first interconnect), wherein the conductive layer of the first multilayer is electrically conductive, or especially wherein the electrical connector is electrically coupled to the conductive layer of the second multilayer (via the second interconnect), wherein the conductive layer of the second multilayer is electrically conductive.

Hence, in specific embodiments, the assembly may comprise a thermal connector thermally coupled to the electrical component and to the conductive layer of the second multilayer, wherein the conductive layer of the second multilayer is thermally conductive, and the electrical component may comprise an electrical connector electrically coupled to the conductive layer of the first multilayer, wherein the conductive layer of the first multilayer is electrically conductive.

In further embodiments, the electrical connector may comprise a first connector and a second connector, especially wherein the first multilayer comprises a first section and a second section, wherein the first section and the second section are electrically separated, and wherein the first connector is electrically coupled to the first section, and wherein the second connector is electrically coupled to the second section.

In further embodiments, the electrical component may comprise an active electrical component. The electrical component may especially comprise a packaged semiconductor.

In particular, the electrical component may comprise one or more of a light source, a driver, and a printed circuit board, especially one or more of a light source, and a driver.

In further embodiments, the electrical component may comprise a passive electrical component, such as a jumper, a resistor, a capacitor, an inductor, or a transformer, et cetera.

The electrical component may especially be compatible with an SMT solder process.

In embodiments, the multilayer stack may have a multilayer stack length L, a multilayer stack width W and a multilayer stack thickness H.

In particular, the multilayer stack length L may be selected from the range of 30-8000 mm, especially from the range of 50-5000 mm, such as from the range of 60-4000 mm, especially from the range of 80-2000 mm, such as from the range of 100-1000 mm. In embodiments, the multilayer stack length L may be at least 30 mm, such as at least 50 mm, especially at least 60 mm, such as at least 80 mm, especially at least 100 mm, such as at least 200 mm, such as at least 500 mm, especially at least 1000 mm. In further embodiments, the multilayer stack length L may be at most 8000 mm, such as at most 5000 mm, especially at most 4000 mm, such as at most 2000 mm, especially at most 1000 mm, such as at most 700 mm, especially at most 500 mm, such as at most 300 mm.

In embodiments, the multilayer stack width W may be selected from the range of 30-8000 mm, especially from the range of 50-5000 mm, such as from the range of 60-4000 mm, especially from the range of 80-2000 mm, such as from the range of 100-1000 mm. In embodiments, the multilayer stack width W may be at least 30 mm, such as at least 50 mm, especially at least 60 mm, such as at least 80 mm, especially at least 100 mm, such as at least 200 mm, such as at least 500 mm, especially at least 1000 mm. In further embodiments, the multilayer stack width W may be at most 8000 mm, such as at most 5000 mm, especially at most 4000 mm, such as at most 2000 mm, especially at most 1000 mm, such as at most 700 mm, especially at most 500 mm, such as at most 300 mm.

In further embodiments, the multilayer stack thickness H may be selected from the range of 15-300 μm, especially from the range of 15-200 μm, such as especially in embodiments about 20-200 μm, such as from the range of 25-150 μm, especially from the range of 30-120 μm, such as from the range of 40-100 μm. Hence, in embodiments, the multilayer stack thickness H may be at least 15 μm, such as at least 20 μm, especially at least 25 μm, such as at least 30 μm, especially at least 40 μm, such as at least 50 μm.

In further embodiments, the multilayer stack thickness H may be at most 300 μm, such as at most 200 μm, especially at most 150 μm, such as at most 120 μm, especially at most 100 μm, such as at most 80 μm, especially at most 70 μm, such as at most 60 μm, especially at most 50 μm.

In further embodiments, the multilayer stack length L may be at least 2 times the multilayer stack width W, i.e. L≥2*W, especially ≥3*W. However, in other embodiments the length and the width may be (about) the same.

The multilayers of the multilayer stack may especially be stacked along the multilayer stack thickness H. In particular, each layer of the multilayers may be stacked along the multilayer stack thickness H. Hence, in specific embodiments, the multilayer stack thickness may be equal to the combined thickness of each layer of the multilayers.

In embodiments, the multilayer stack may comprise two or more multilayers, especially three or more multilayers, such as four or more multilayers. The two or more multilayers may together provide the multilayer stack thickness H, the multilayer stack length L and the multilayer stack width W.

In further embodiments, the multilayer stack may especially consist of two multilayers, or especially of three multilayers.

In embodiments wherein the multilayer stack comprises three or more multilayers, especially two or more of the multilayers may be a first multilayer, i.e., two or more of the multilayers may comprise openings through which an interconnect can connect an electrical component to a different multilayer, especially a second multilayer, or especially a different first multilayer.

In particular, the flexible support layer may have a support thickness selected from the range of 10-50 μm, especially from the range of 15-30 μm. In (other) embodiments, the flexible support layer may have a support thickness of at least 10 μm, especially at least 15 μm, such as at least 18 μm, especially at least 20 μm, such as at least 25 μm. In further embodiments, the flexible support layer may have a support thickness of at most 80 μm, such as at most 50 μm, especially at most 30 μm, such as at most 25 μm, especially at most 23 μm.

In embodiments, the multilayer stack may comprise a monolithic bent layer element. Especially, the monolithic bent layer element may comprise the first multilayer and the second multilayer. Hence, the monolithic bent layer element may comprise a first section and a second section separated by a bend, wherein the first section corresponds to the first multilayer, and wherein the second section corresponds to the second multilayer.

The multilayer stack may especially be elongated along the multilayer stack length L (with respect to the multilayer stack width W and the multilayer stack thickness H). In embodiments, a plurality of electrical component may be arranged along the multilayer stack length L. In further embodiments, the monolithic bent layer may especially be bent along the multilayer stack width W, i.e., bending of the layer element (see below) may essentially reduce the width and increase the thickness of the layer element, while essentially not affecting the length of the layer element.

In embodiments, the conductive layers of the different multilayers, especially of the first multilayer and the second multilayer, may be electrically separated, i.e., they are not directly electrically coupled. They may, however, be electrically coupled via an electrical component.

In embodiments, the first interconnect may be electrically separated from the second conductive layer. In particular, the first interconnect may be physically separated from the second conductive layer. Similarly, in further embodiments, the second interconnect may be electrically separated from the first conductive layer. In particular, the second interconnect may be physically separated from the first conductive layer.

In embodiments, the flexible support layer may be electrically insulating, i.e., the flexible support layer may not be electrically conductive.

The term “electrically conductive” may herein refer to a material having a conductivity of at least 10⁻⁸ S/cm, such as at least 10⁻⁷ S/cm, especially at least 10⁻⁶ S/cm, such as at least 10⁻⁵ S/cm, especially at least 10⁻⁴ S/cm, such as at least 10⁻³ S/cm, especially at least 10⁻² S/cm, such as at least at least 10⁰ S/cm, especially at least 10¹ S/cm, such as at least 10² S/cm, especially at least 10³ S/cm. In particular, herein the term “electrically conductive” may refer to a material having a conductivity (at room temperature) of at least 1·10⁵ S/m, such as at least 1·10⁶ S/m. Herein a conductivity of an insulated material may especially be equal to or smaller than 1·10⁻¹⁰ S/m, especially equal to or smaller than 1·10⁻¹³ S/m. Herein a ratio of an electrical conductivity of an isolating material (insulator) and an electrical conductivity of an electrically conductive material (conductor) may especially be selected smaller than 1·10⁻¹⁵.

The term “thermally conductive” may herein refer to a material having a thermal conductance of at least 5 W/m/K, especially at least 10 W/m/K, such as at least 20 W/m/K, especially at least 30 at least 10 W/m/K, such as at least 50 at least 10 W/m/K, especially at least 80 W/m/K, such as at least 100 W/m/K, especially at least 150 W/m/K, such as at least 200 W/m/K, especially at least at least 300 W/m/K, such as at least at least 400 W/m/K. In further embodiments, the thermally conductive material may comprise of one or more of copper, aluminum, silver, gold, silicon carbide, aluminum nitride, boron nitride, aluminum silicon carbide, beryllium oxide, a silicon carbide composite, aluminum silicon carbide, a copper tungsten alloy, a copper molybdenum carbide, carbon, diamond, and graphite. Alternatively, or additionally, the thermally conductive material may comprise or consist of aluminum oxide.

In a second aspect, the invention may provide a light generating device comprising the assembly according to the invention, especially wherein the electrical component comprises a light source. The term “light source” may also relate to a plurality of light sources, such as 2-20 (solid state) LED light sources. Hence, the term LED may also refer to a plurality of LEDs. In embodiments, the light source may comprise one or more of a LED filament and a LED string.

In embodiments, the electrical component, especially the light source, may comprise a solid state light source (such as a LED or laser diode).

In further embodiments, the electrical component may comprise a light emitting diode (as light source) arranged on a ceramic body. Such embodiments may be beneficial over metal core PCB (MCPDB) when it comes to switching reliability. The difference in coefficient of thermal expansion (CTE) between MCPCB and the ceramic body of the LED may limit the number of switching cycles and/or the maximum LED temperature. However, the assembly of the present invention, especially the multilayers, particularly the flexible support layers, may be flexible and may provide reduced strain on the solder joint, facilitating an increased number of switching cycles and/or an increased maximum LED temperature.

In embodiments, the light generating device may specially be selected from the group comprising a lamp and a luminaire.

In a further aspect, the invention may provide a method for providing an assembly. The method may comprise providing (a) the first (conductive) interconnect, (b) the second (conductive) interconnect, (c) the electrical component, (d) the first multilayer and the second multilayer. The method may further comprise connecting the electrical component (i) by the first interconnect to the conductive layer of the first multilayer and (ii) by the second interconnect to the conductive layer of the second multilayer, especially via the opening of the first multilayer.

In embodiments, one or more of the first interconnect and the second interconnect comprise a solder material, especially wherein the solder material is one or more of thermally conductive and electrically conductive.

In embodiments, the method may comprise an SMT process. The term “SMT process” may herein especially refer to a process by which an electrical component in attached to (the surface of) a conductive layer, especially of a PCB, especially via soldering of the electrical component to (the surface of) the conductive layer. Hence, the method may comprise soldering of the electrical component to one or more of the conductive layers of the multilayer stack, especially to the conductive layer of the first multilayer, or especially to the conductive layer of the second multilayer, more especially to all of the conductive layers of the multilayer stack.

In embodiments, the second interconnect and the conductive layer of the second multilayer are thermally conductive, and the method may comprise: providing a thermal connector to the electrical component, and connecting the electrical component via the thermal connector and the second interconnect to the conductive layer of the second multilayer. Hence, in such embodiments, the thermal connector may be thermally coupled to the second multilayer.

In embodiments, the electrical component may comprise an electrical connector, wherein the first interconnect and the conductive layer of the first multilayer are electrically conductive, and wherein the method comprises connecting the electrical connector and the first interconnect. Hence, in such embodiments, the electrical connector may be electrically coupled to the first multilayer.

In embodiments, the method may comprise providing a layer element comprising (i) the flexible support layer comprising and (ii) the conductive layer.

In further embodiments, the method may comprise bending the layer element to provide a monolithic bent layer element, wherein the monolithic bent layer element comprises the first multilayer and the second multilayer. Hence, by bending the layer element, part of the flexible support layer of the layer element may become the flexible support layer of the first multilayer, and part of the flexible support layer of the layer element may become the flexible support layer of the second multilayer. Such embodiments may be particularly convenient for providing the assembly. In particular, such embodiments may facilitate automated assembly.

Hence, the layer element may comprise a (single) flexible support layer with a conductive layer. In particular, the layer element may comprise a flexible support layer with two conductive layers arranged on opposite sides of the flexible support layer. In such embodiments, the conductive layers may especially be arranged such that after bending to provide the monolithic bent layer element, the two conductive layers are not in direct electrical contact. In particular, after bending, the conductive layers may be physically separated, i.e., they do not touch.

Further, the method may comprise bending the layer element to provide a multilayer stack with alternating conductive layers and flexible support layers.

Hence, in embodiments, the method may comprise bending the layer element to provide the monolithic bent layer element such that each conductive layer is electrically separated from the other conductive layers. In particular, the method may comprise bending the layer element to provide the monolithic bent layer element such that each conductive layer is physically separated from the other conductive layers, i.e., different conductive layers do not touch.

In embodiments, the method may further comprise providing the first multilayer by arranging the (respective) conductive layer on the (respective) flexible support layer.

In further embodiments, the method may comprise providing the second multilayer by arranging the (respective) conductive layer on the (respective) flexible support layer.

In further embodiments, the method may comprise providing the opening in the first multilayer, especially in the flexible support layer of the first multilayer. The method may especially comprise punching the opening in the first multilayer, especially in the flexible support layer of the first multilayer.

In a further aspect, the invention may provide an assembly obtainable from the method of the invention.

The light generating device may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, green house lighting systems, horticulture lighting, or LCD backlighting.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1A-B schematically depict embodiments of the assembly and of the method.

FIG. 2 schematically depicts an embodiment of the light generating device.

FIG. 3 schematically depicts further embodiments of the light generating device.

The schematic drawings are not necessarily on scale.

### DETAILED DESCRIPTION OF THE EMBODIMENTS

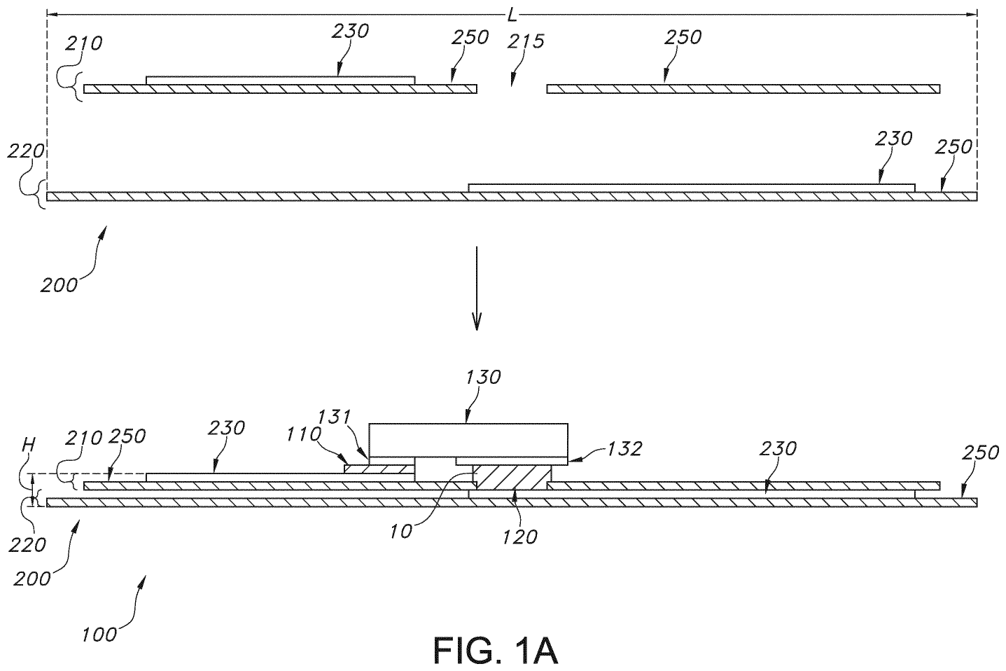

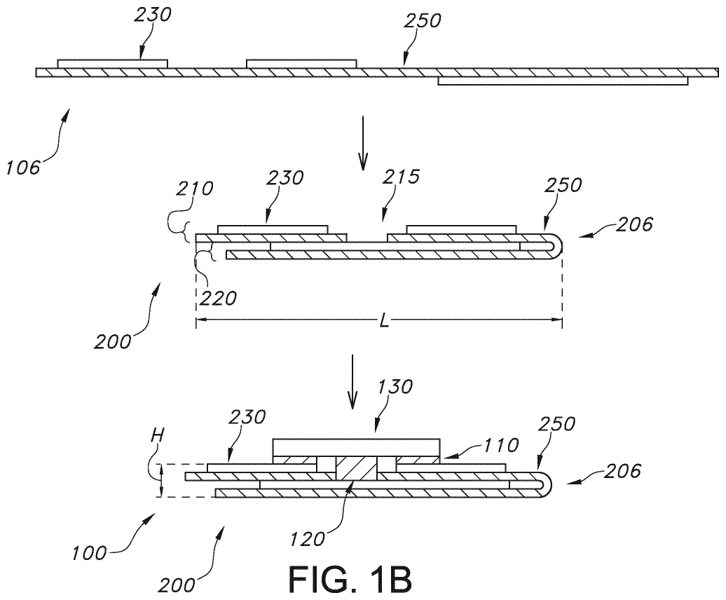

FIG. 1A schematically depicts an embodiment of the assembly 100. In the depicted embodiment, the assembly 100 comprises a first (conductive) interconnect 110, a second (conductive) interconnect 120, an electrical component 130, and a multilayer stack 200. The multilayer stack comprises a first multilayer 210 and a second multilayer 220. Each multilayer 210,220 of the multilayer stack 200, here especially the first multilayer 210, and the second multilayer 220, comprises a flexible support layer 250 and a conductive layer 230. The first interconnect 110 connects the electrical component 130 and the conductive layer 230 of the first multilayer 210. The first multilayer 210 comprises an opening 215 (see top half of FIG. 1), wherein at least part of the second interconnect 120 is arranged in the opening 215. The second interconnect 120 connects the electrical component 130 and the conductive layer 230 of the second multilayer 220. In particular, in the depicted embodiment, The second interconnect 120 connects the electrical component 130 and the conductive layer 230 of the second multilayer 220 via the opening 215. Especially, the first interconnect 110, the second interconnect 120, and the conductive layers 230 may each individually be one or more of thermally conductive and electrically conductive.

In embodiments, one or more of the first interconnect 110 and the second interconnect 120 may comprise a solder material 10, especially wherein the solder material 10 is one or more of thermally conductive and electrically conductive. In the depicted embodiment, the second interconnect 120 comprises a solder material. In further embodiments, the second interconnect may consist of the solder material. Hence, the solder material 10 may functionally couple, especially electrically coupled, or especially thermally couple, the electrical component 130 to the conductive layer 230 of the second multilayer 220.

In the depicted embodiment, the electrical component 130 comprises an electrical connector 131 wherein the electrical connector 131 is electrically coupled to the conductive layer 230 of the first multilayer 210 (via the first interconnect 110), wherein the conductive layer 230 of the first multilayer 210 is electrically conductive, and wherein the first interconnect 110 is electrically conductive.

Similarly, in the depicted embodiment, the electrical component comprises a thermal connector 132, wherein the thermal connector 132 is thermally coupled to the electrical component 130 and thermally coupled to the conductive layer 230 of the second multilayer 220 via the second interconnect 120, wherein the conductive layer 230 of the second multilayer 210 is thermally conductive, and wherein the second interconnect 120 is thermally conductive. Hence, in the depicted embodiment, the conductive layer 230 of the first multilayer 210 may be configured for providing electrical connections, especially configured as a PCB, whereas the conductive layer 230 of the second multilayer 220 may comprise a heat sink.

In the depicted embodiment, the multilayer stack 200 has a multilayer stack length L selected from the range of 50-5000 mm, a multilayer stack width W selected from the range of 50-5000 mm, and a multilayer stack thickness H selected from the range of 20-200 μm. The multilayer stack width W may especially be perpendicular to both the multilayer stack length L and the multilayer stack thickness H.

FIG. 1A further schematically depicts an embodiment of the method for providing the assembly 100. The method may comprise providing the first (conductive) interconnect 110, the second (conductive) interconnect 120, the electrical component 130, the first multilayer 210, and the second multilayer 220. The method may further comprise connecting the electrical component 130 to the conductive layer 230 of the first multilayer 210 by the first interconnect 110. The method may further comprise connecting the electrical component 130 to the conductive layer 230 of the second multilayer 220 by the second interconnect 120 via the opening 215.

Hence, the method may comprise functionally coupling the electrical component 130 to the conductive layers 230 by providing the first interconnect 110 and the second interconnect 120. The method may especially comprise an SMT process.

In embodiments, one or more of the first interconnect 110 and the second interconnect 120 comprise a solder material 10. Hence, the method may comprise one or more of (i) providing a solder material 10 to provide a first interconnect 110 connecting the electrical component 130 and the conductive layer 230 of the first multilayer 210, and (ii) providing a solder material 10 to provide a second interconnect 120 connecting the electrical component 130 and the conductive layer 230 of the second multilayer 220.

In embodiments, the second interconnect 120 and the conductive layer 230 of the second multilayer 220 are thermally conductive, and the method may comprise providing a thermal connector 132 to the electrical component 130 and connecting the electrical component 130 via the thermal connector 132 and the second interconnect 120 to the conductive layer 230 of the second multilayer 220, especially such that the thermal connector 132 is thermally coupled to the second multilayer 210. In such embodiments, the second multilayer may especially be thermally conductive.

In further embodiments, the electrical component 130 may comprise an electrical connector 131, and the method may comprise connecting the electrical connector 131 and the first interconnect 110, especially such that the electrical connector 131 is electrically coupled to the conductive layer 230 of the first multilayer 210. In such embodiments, the first interconnect 110 and the conductive layer 230 of the first multilayer 210 may be electrically conductive.

In embodiments, the method may comprise providing the first multilayer 210 by arranging the (respective) conductive layer 230 on the (respective) flexible support layer 250.

In further embodiments, the method may comprise providing the second multilayer 220 by arranging the (respective) conductive layer 230 on the (respective) flexible support layer 250.

In further embodiments, the method may comprise providing the opening 215 in the flexible support layer 250 of the first multilayer 210.

FIG. 1B schematically depicts an embodiment of the method, wherein the method comprises providing a layer element 106 comprising the flexible support layer 250 and the conductive layer 230, and bending the layer element 106 to provide a monolithic bent layer element 206, wherein the monolithic bent layer element 206 comprises the first multilayer 210 and the second multilayer 220. In addition, in the depicted embodiment, the method further comprises providing the opening 215 in the flexible support layer 250 of the first multilayer 210. In particular, in embodiments, the method may comprise punching an opening 215 in the flexible support layer 250 of the first multilayer 210.

In the depicted embodiment, the layer element 106 comprises a single flexible support layer 250 and two conductive layers 230 arranged at opposite sides of the flexible support layer 250. In particular, in the depicted embodiment, the method comprises bending the layer element 106 to provide a monolithic bent layer element 206 with alternating conductive layers 230 and flexible support layers 250 (along the multilayer stack thickness H).

FIG. 1B further schematically depicts an embodiment of the assembly 100, wherein the multilayer stack 200 comprises a monolithic bent layer element 206, wherein the monolithic bent layer element 206 comprises the first multilayer 210 and the second multilayer 220.

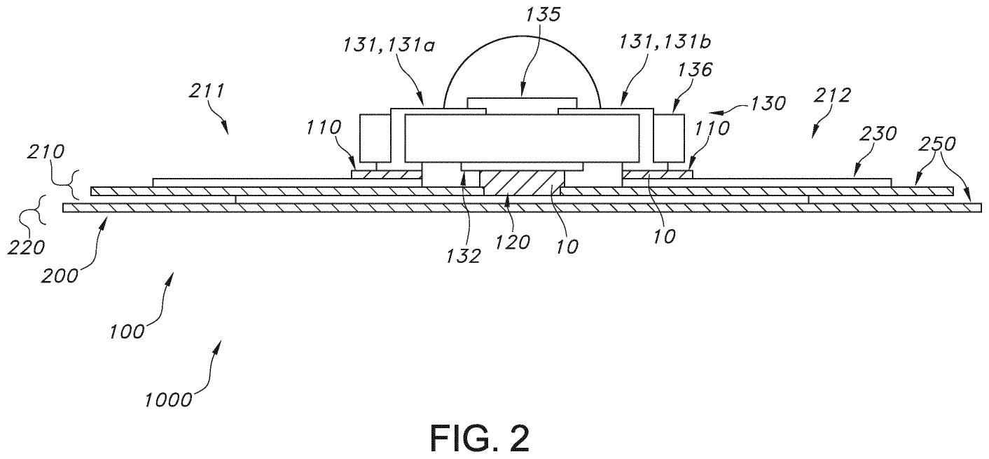

FIG. 2 schematically depicts an embodiment of the assembly 100, wherein the first multilayer 210 comprises a first section 211 and a second section 212, wherein the first section 211 and the second section 212 are electrically separated, i.e., the first section 211 and the second section 212 are not directly electrically coupled. In particular, the first section 211 and the second section 212 may be physically separated. In further embodiments, the electrical connector 131 may comprise a first connector 131a and a second connector 131b, wherein the first connector 131a is electrically coupled to the first section 211, and wherein the second connector 131b is electrically coupled to the second section 212. Hence, the electrical component 230 may be electrically coupled to both the first section 211 and to the second section 212 via the first connector 131a and the second connector 131b, respectively.

In embodiments, the electrical component 130 may comprise one or more of a light source, and a driver. In the depicted embodiment, the electrical component 130 comprises a light source.

Hence, FIG. 2 further schematically depicts an embodiment of a light generating device 1000, wherein the light generating device 1000 comprises the assembly 100, wherein the electrical component 130 comprises a light source.

In particular, in embodiments, the electrical component 130 may comprises a solid state light source. Especially, in the depicted embodiment, the electrical component 130 may comprise a light emitting diode 135 arranged on a ceramic body 136.

Referring to FIG. 2, such assembly may be intended to reduce the drawbacks of FPC while keeping the advantage of better switching reliability. For instance, it may allow to have larger heat spreader surfaces in a Cu layer on the second PI film which may improve the thermal performance of the assembly. Further, the punched hole may have lower tolerances compared to e.g. the screen printed Cu gaps allowing for the finer LED footprints such as used for high power ceramic LEDs. If needed, the hole can be kept smaller to increase the creepage and the layer on the second PI film can have additional creepage towards the other Cu heat spreaders.

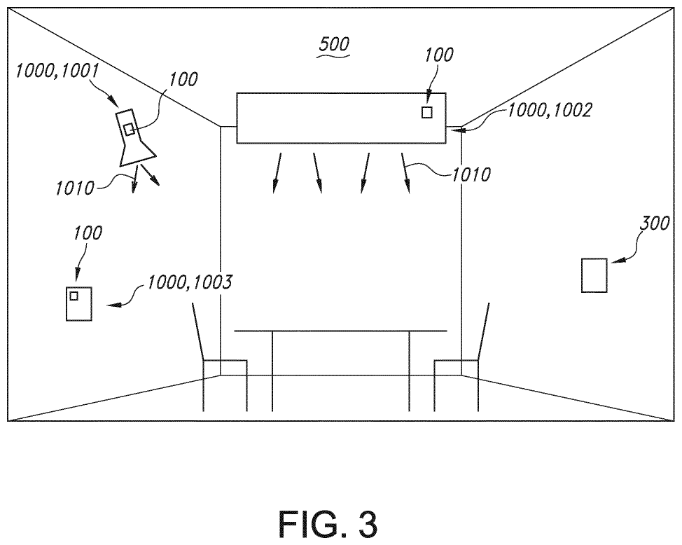

FIG. 3 schematically depicts another embodiment of the assembly 100, wherein the assembly is integrated in light generating devices 1000. In particular, FIG. 3 schematically depicts light generating devices 1000, such as a lamp 1001, and a luminaire 1002, and a lighting control element 1003, such as a user interface, like a graphical user interface. Reference 1010 indicates the light that is generated by a light generating device 1000. Especially, this light is visible light, such as white light. The lighting control element 1003 may also be a portable device, such as an I-phone or Smartphone.

The term “plurality” refers to two or more. Furthermore, the terms “a plurality of” and “a number of” may be used interchangeably.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%. Moreover, the terms “about” and “approximately” may also relate to 90% or higher, such as 95% or higher, especially 99% or higher, even more especially 99.5% or higher, including 100%. For numerical values it is to be understood that the terms “substantially”, “essentially”, “about”, and “approximately” may also relate to the range of 90%-110%, such as 95%-105%, especially 99%-101% of the values(s) it refers to.

The term “comprise” also includes embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The term “functionally coupled” may in embodiments refer to a physical connection or mechanical connection between at least two elements, such as via one or more of a screw, a solder, an adhesive, a melt connection, etc. Alternatively or additionally, the term “functionally coupled” may in embodiments refer to an electrically conductive connection between at least two elements. When two (or more) elements have an electrical conductive connection, then there may be a conductivity (at room temperature) between the two (or more) elements of at least 1·10⁵ S/m, such as at least 1·10⁶ S/m. In general, an electrically conductive connection will be between two (or more) elements each comprising an electrically conductive material, which may be in physical contact with each other or between which an electrically conductive material is configured. Herein a conductivity of an insulated material may especially be equal to or smaller than 1·10⁻¹⁰ S/m, especially equal to or smaller than 1·10⁻¹³ S/m. Herein a ratio of an electrical conductivity of an isolating material (insulator) and an electrical conductivity of an electrically conductive material (conductor) may especially be selected smaller than 1·10⁻¹⁵.

The devices, apparatus, or systems may herein amongst others be described during operation. As will be clear to the person skilled in the art, the invention is not limited to methods of operation, or devices, apparatus, or systems in operation.

The term “further embodiment” and similar terms may refer to an embodiment comprising the features of the previously discussed embodiment, but may also refer to an alternative embodiment.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, “include”, “including”, “contain”, “containing” and the like are to be construed in an inclusive sense as opposed to an exclusive or exhaustive sense; that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings. Moreover, if a method or an embodiment of the method is described being executed in a device, apparatus, or system, it will be understood that the device, apparatus, or system is suitable for or configured for (executing) the method or the embodiment of the method, respectively.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

Hence, amongst others the invention provides a way to make a multilayered PCB assembly out of one or more thin flexible film substrates. In particular, the invention may provide an embodiment for a module assembly with ceramic high power LEDs.

In embodiments, an assembly may be provided by two or more multi-layers, which are based on a single multi-layer that is folded into a stack of the two or more multi-layers. Such assembly is herein also indicated as a monolithic bent layer element. An assembly of two or more multi-layers may also be provided by stacking the multi-layers, where two or more of the multi-layer are not based on a single multi-layer that is folded into a stack of the two or more multi-layers. For instance, in embodiments two or more multi-layers are provided as such, and may be stacked to provide the assembly.

1. A light generating device comprising (a) a first interconnect, (b) a second interconnect, (c) a solid state light source, and (d) a multilayer stack comprising a first multilayer and a second multilayer, wherein:
each multilayer of the multilayer stack comprises (i) a flexible support layer, and (ii) a conductive layer;
the first interconnect connects the solid state light source and the conductive layer of the first multilayer;
the first multilayer comprises an opening, wherein at least part of the second interconnect is arranged in the opening;
the second interconnect connects the solid state light source and the conductive layer of the second multilayer; and
the first interconnect, the second interconnect, and the conductive layers are each individually one or more of thermally conductive and electrically conductive; and
wherein the multilayer stack comprises a monolithic bent layer element, wherein the monolithic bent layer element comprises the first multilayer and the second multilayer, the monolithic bent layer element comprises a first section and a second section separated by a bent, wherein the first section corresponds to the first multilayer, and wherein the second section corresponds to the second multilayer.

2. The light generating device according to claim 1, wherein one or more of the first interconnect and the second interconnect comprises a solder material, and wherein the flexible support layer comprises polyimide.

3. The light generating device according to claim 1, comprising a thermal connector, wherein the thermal connector is thermally coupled to the solid state light source and thermally coupled to the conductive layer of the second multilayer via the second interconnect, wherein the conductive layer of the second multilayer is thermally conductive.

4. The light generating device according to claim 1, wherein the solid state light source comprises an electrical connector, wherein the electrical connector is electrically coupled to the conductive layer of the first multilayer, wherein the conductive layer of the first multilayer is electrically conductive.

5. The light generating device according to claim 4, wherein the electrical connector comprises a first connector and a second connector, and wherein the first multilayer comprises a first sectiones and a second section, wherein the first section and the second section are electrically separated, and wherein the first connector is electrically coupled to the first section, and wherein the second connector is electrically coupled to the second section.

6. The light generating device according to claim 1, wherein the multilayer stack has a multilayer stack length (L) selected from the range of 50-5000 mm, a multilayer stack width selected from the range of 50-5000 mm, and a multilayer stack thickness (H) selected from the range of 15-200 μm.

7. The light generating device according to claim 1, wherein the conductive layers are arranged at opposite sides of the flexible support layer.

8. The light generating device according to claim 1, wherein the solid state light source comprises a light emitting diode arranged on a ceramic body.

9. A lamp or a luminaire comprising the light generating device according to claim 1.

10. A method for providing the light generating device according to claim 1, wherein the method comprises:
providing (a) the first interconnect, (b) the second interconnect, (c) the solid state light source, (d) the first multilayer and the second multilayer; and
connecting the solid state light source (i) by the first interconnect to the conductive layer of the first multilayer and (ii) by the second interconnect via the opening to the conductive layer of the second multilayer;
and wherein the method further comprises:
providing a layer element comprising the flexible support layer and the conductive layer; and
bending the layer element to provide a monolithic bent layer element, wherein the monolithic bent layer element comprises the first multilayer and the second multilayer; and
wherein the monolithic bent layer element comprises a first section and a second section separated by a bent, wherein the first section corresponds to the first multilayer, and wherein the second section corresponds to the second multilayer.

11. The method according to claim 10, wherein one or more of the first interconnect and the second interconnect comprise a solder material.

12. The method according to claim 1, wherein the second interconnect and the conductive layer of the second multilayer are thermally conductive, and wherein the method comprises:
providing a thermal connector to the solid state light source and connecting the solid state light source via the thermal connector and the second interconnect to the conductive layer of the second multilayer.

13. The method according to claim 10, wherein the solid state light source comprises an electrical connector, wherein the first interconnect and the conductive layer of the first multilayer are electrically conductive, and wherein the method comprises:
connecting the electrical connector and the first interconnect.

14. (canceled)

15. The method according to claim 10, wherein the layer element comprises a single flexible support layer and two conductive layers arranged at opposite sides of the flexible support layer.

16. The method according to claim 10, wherein the method comprises bending the layer element to provide a monolithic bent layer element with alternating conductive layers and flexible support lavers along the multilayer stack thickness H.
